(19) United States
(12) Patent Application Publication
(10) Pub. No.: US 2018/0003759 A1
(43) Pub. Date: Jan. 4, 2018

(54) SYSTEM AND METHOD FOR ACCURATELY MONITORING AND COMPUTING AGEING LIFE OF A TRANSFORMER IN A SMART GRID FRAMEWORK

(71) Applicant: Tech Mahindra Limited, Pune (IN)

(72) Inventors: Arya Kumar Bhattacharya, Hyderabad (IN); Sayantan Hazra, Hyderabad (IN); Amrita Agnes George, Malappuram (IN)

(21) Appl. No.: 15/498,186

(22) Filed: Apr. 26, 2017

(30) Foreign Application Priority Data
Jun. 30, 2016 (IN) 201621022408

(51) Int. Cl. G01R 31/02; G01R 31/00

(52) U.S. Cl. CPC G01R 31/027; G01R 31/003

(57) ABSTRACT

The present INVENTION envisages a system and method for accurately calculating the ageing life of the transformer. The system includes monitoring devices to receive the various transformer parameters in real-time which are further processed according to the enhanced formulation proposed by the present invention in a computing platform and the precise transformer ageing life is delivered. Specifically, the method is provided for enhancing the thermal model accuracy by incorporating empirical factors thereby bringing it at par with accuracy levels of DP method whilst maintaining the facility of real-time estimation within a Smart-Grid framework

### CROSS-REFERENCE TO RELATED APPLICATIONS

This application claims priority to Indian Patent Application No. 201621022408, filed on Jun. 30, 2016, the disclosure of which is incorporated by reference in its entirety.

### FIELD OF THE INVENTION

The present invention relates to the field of running transformers in a smart grid and more particularly, the present invention relates to system and method for loss of life calculation for ageing assessment of transformers.

### DEFINITIONS OF TERMS USED IN THE SPECIFICATION

The expression ‘OIP’ used hereinafter in the specification refers to but is not limited to oil impregnated paper;
The expression ‘EIS’ used hereinafter in the specification refers to but is not limited to an electrical insulation system;
The expression ‘DP’ used hereinafter in the specification refers to but is not limited to Degree of Polymerization;
The expression ‘TOT’ used hereinafter in the specification refers to but is not limited to top oil temperature;
The expression ‘FIST’ used hereinafter in the specification refers to but is not limited to the hottest spot temperature of transformer; and
The above definitions are in addition to those expressed in the art.

### BACKGROUND OF THE INVENTION

Transformers are integral and inevitable part of the electric power system and its failure can seriously disturb the balance of the system, at times even leading to blackouts and also loss of huge revenue. Transformer failures can occur either randomly due to external factors like short circuit in the transmission line, lightning, and the like. Or due to ageing. Hence quantification of ageing is important and a useful information for power engineers and operators in planning and scheduling of maintenance practices and efficient loading, reducing failures as much as possible.

Ageing of a transformer means the deterioration of the winding insulation with time and the most commonly used transformer insulation is oil impregnated paper (OIP). Aging is defined as the irreversible changes of properties of an electrical insulation system (EIS) due to action of one or more factors of influences. The various stresses acting on the insulation are thermal, electrical, mechanical and environmental which give rise to different mechanisms of aging. Thermal aging is considered to continuously take place in transformer insulation as it follows from the elevated operating temperature of the winding, and the heating of the winding is in turn caused by losses in the transformer, which persist as long as the transformer operates.

The most commonly used transformer insulation is oil impregnated paper (OIP). The transformer insulation which is made of paper or cellulose is a natural polymer of glucose molecules. Degree of Polymerization (DP) is the average number of glucose monomers in the polymer chain or the average length of the cellulose fiber. Since the mechanical strength of cellulose material depends on the length and condition of the fibers, DP is a good indicator of the transformer insulation health. For a newly manufactured transformer the DP is taken to be between 1000 and 1200 which keeps on decreasing as the transformer operates and DP value at about 200 is considered as the end of life criteria of transformers. The degradation of cellulose in electrical insulation paper occurs via complex sequences of low temperature chemical reactions. The processes involve chain scission (depolymerisation) and the release of breakdown products such as hydrogen, short chain hydrocarbons, carbon monoxide, carbon dioxide and water. The three mechanisms of ageing due to water, oxygen and heat are hydrolysis, oxidation and pyrolysis respectively. All the three ageing mechanisms have the common effect of incision of cellulose chain along with the release of other byproducts.

The two different methods commonly used for assessment of ageing are first, a method based on DP values and second, method based on thermal models of transformers.

Though DP values give a precise idea about the condition of insulation, its measurement from insulation specimen of a working transformer is expensive and time consuming. U.S. Pat. No. 8,781,756 B2 discusses about an analysis which gives an indirect estimate of DP. The amount of dissolved gases in the transformer oil at a given point in time is used to estimate DP along with the effect of through fault and maintenance events. The estimate of DP is then used to evaluate the remaining useful life of the transformer. The major drawback of this method is that only event based data is used to estimate DP and hence hourly or daily information on a running transformer regarding its life is not deducible by this method.

The thermal assessment is done taking into consideration the uneven temperature distribution inside a transformer and it can be seen that temperature is higher in the top oil region due to convection and nature of the cooling system design. The temperature will be highest at a particular point of the winding in the top region of the transformer and that spot is considered as the hottest spot and the insulation deterioration is considered at the maximum at this region. Thus the ageing assessment based on the top oil temperature (TOT) and hottest spot temperature (HST) gives a fairly accurate measure of insulation degradation. However reliable measurements of these temperatures using sensors or by any other physical means are not possible in the real life scenario.

US 2012/0070903 A1 discloses a method for measuring the real hot spot temperature in a transformer using chemical compounds or tracers which may transform at a given temperature to form a residue such as soluble gas. From the presence of residue in the oil, the operator will be able to deduce the hot spot temperature. This method requires extracting the oil and testing the sample for residue each time to find the hot spot temperature which is a time consuming process. Moreover the hourly variation of hot spot temperature may not be deducted accurately. Hence based on laboratory tests and experience, IEEE and IEC have suggested various models to find out the maximum temperature acting on the transformers.

IEEE Clause 7 thermal model is simple and requires less number of inputs, hence widely used. The input to this model includes the loading and ambient temperature profile along with the design values of the transformer based on its construction and cooling system. Even for a small interval of time the corresponding loss of life can be calculated easily. However this method does not take into account the accelerative effects of water and oxygen.

US 2013/0243033 A1 discloses about a method of assessing remaining life of transformer using the direct method of obtaining and analyzing a sample of insulation material that has been in contact with the fluid at its top surface and also by the indirect method of assessing remaining life as a function of measured temperature of fluid at its top surface and the corresponding registered time. The transformer under consideration had a temperature sensor and a fluid permeable case for holding a piece of pressboard accessible from exterior at the top surface of the transformer. This method cannot be used for the transformers under operation due to difficulty in conducting such measurements. In this work, equivalent ageing rate equations of IEEE clause 7 thermal models is modified such that it takes into account the effects of other degradation agents along with temperature. The modification is done based on a comparison made between the loss of life results obtained from the direct (DP) method and indirect (IEEE thermal model) method. The DP values varying with time were obtained from a controlled laboratory ageing experiment conducted on prorated transformers. The sample loading and ambient temperature data for IEEE thermal model was obtained from a transformer in North America and modulated according to the experimental conditions.

Accordingly, there exists a need for a system and method for loss of life assessment of the transformer which overcomes abovementioned drawbacks.

### OBJECTS OF THE INVENTION

Some of the objects of the present INVENTION aimed to ameliorate one or more problems of the prior art or to at least provide a useful alternative are described herein below:

An object of the present INVENTION is to accurately calculate the ageing life of the transformer in real-time.

Another object of the said INVENTION is to accurately measure the hot spot temperature of the transformer.

Yet another objective of the present INVENTION is to enhance the thermal model accuracy by incorporating empirical factors thereby bringing it at par with accuracy levels of DP method.

Other objects and advantages of the present INVENTION will be more apparent from the following description when read in conjunction with the accompanying figures, which are not intended to limit the scope of the present INVENTION.

### SUMMARY OF THE INVENTION

Accordingly, the present invention provides a system and methods for precisely measuring the ageing life of the transformer in a smart grid framework by enhancing the thermal model of ageing life calculation. The system provides a smart grid framework in which a transformer is connected to a monitoring and computing platform. The computing platform is configured to receive the monitored information of the transformer in real-time and can store and process the received data according to the formulation proposed by the present invention and delivers the precise ageing life of the transformer. The thermal model according to the present invention considers the effects of not only temperature but also other various ageing factors including but not limited to water, oxygen etc. The thermal model is improved further by introducing appropriate correction factors to consider the effects of different ageing factors which to improve its accuracy. The smart grid system allows to monitor and compute the transformer parameters remotely in real-time.

### BRIEF DESCRIPTION OF THE ACCOMPANYING DRAWINGS:

A system and method for loss of life calculation for ageing assessment of running transformers in a smart grid framework of the present INVENTION will now be described with the help of accompanying drawings, in which:

FIG. 1 illustrates a graphic representation of Equivalent Ageing rate factor (Feqa) vs Time (Hours) by method using Thermal model, according to the present invention;

FIG. 2 illustrates a graphic representation of typical loading cycle of stress accelerated experiment, according to the present invention;

FIG. 3 illustrates a graphic representation of loss of Life VS Time for constant HST and experimental HST profile, according to the present invention;

FIG. 4 illustrates a graphic representation of experimentally measured DP values with Time (in Hours) according to the present invention;

FIG. 5 illustrates a graphic representation of Variation of 1/DP with Time according to the present invention;

FIG. 6 illustrates a graphic representation of relative ageing rate factor and equivalent ageing rate factor with time by method using DP values according to the present invention;

FIG. 7 illustrates a graphic representation of percent loss of life VS Time by DP method according to the present invention;

FIG. 8 illustrates the graphic representation of Loss of Life (%) with Time (Hours) by Thermal Model, and the DP method, according to the present invention;

FIG. 9 illustrates a graphic representation of Loss of Life Curves by direct method (using DP values) and indirect method (Thermal model with modified F_eqa equation) according to the present invention.

### DETAILED DESCRIPTION OF THE ACCOMPANYING DRAWINGS

A preferred embodiment will now be described in detail with reference to the accompanying drawings. The preferred embodiment does not limit the scope and ambit of the INVENTION. The description provided is purely by way of example and illustration.

The embodiments herein and the various features and advantageous details thereof are explained with reference to the non-limiting embodiments in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The present INVENTION provides a system and method for accurately calculating the ageing life of the transformer. Specifically, the method is provided for enhancing the thermal model accuracy by incorporating empirical factors thereby bringing it at par with accuracy levels of DP method whilst maintaining the facility of real-time estimation within a Smart-Grid framework. The said enhancement being attained using a correction factor based on an exponential factor of time, empirically formulated and introduced into the equivalent ageing rate equation of thermal model by analyzing the deviations between the LoL curves obtained using the two alternate approaches. The stated correction factor is developed based on accelerated ageing experiments conducted on a model transformer. For applicability of this factor in the ageing assessment of a typical power transformer a time scale factor is introduced as part of the exponential coefficient of the correction factor. Herein the exponential coefficient of the said correction factor is modified empirically to adapt it for the equivalent ageing rate calculation of a distribution transformer. The confirmation of accuracy of the method of the present invention for both power and distribution transformers is obtained by first achieving the desired life of the transformers when loaded at one pu consistently, and then proving the 10 degrees Celsius thumb rule (degree of impact on transformer life of consistent 10 degrees Celsius enhanced loading) to hold good in both cases.

In one aspect, the present invention provides a system for accurately monitoring and computing ageing life of a transformer (hereinafter “the system”). The system comprises of a plurality of power transformers distributed in power transmission network or a power distribution (to retail users) network. Furthermore, the system comprises a computing platform connected to each transformer of the plurality of transformers. Specifically, the computing platform comprises means to receive the data, a memory unit to store the data, a processor to execute instructions, and display device to display result. The transformer and the computing platform have real-time connectivity. The computing platform can be any kind of combination of I/O; storage and processing arrangement. Appropriate arrangement is made to compute and record the loads of transformer (watts or analogous units) at every 1 second (interval could vary) interval, and ambient temperature using a weather thermometer at every 1 hour interval.

The system also comprises a module configured on the computing platform for computing and recording loads of transformer and ambient temperature at predefined interval. The module of the present invention, which in turn is derived from the formulation proposed by the present invention as described herein, is installed on this computing platform.

The module is configured to calculate the LoL (loss of life) on every one hour and (a) displaying it and (b) archiving it. User anytime can query the LoL between any two entered time periods and the computing platform calculates and returns the value.

When the first instant (of the time period) coincides with the start of transformer operation, the LoL corresponds to the actual life of the transformer. The computing platform and a smart grid framework are in real-time connection to capture the running hourly loss-of-life from different transformers.

In another aspect, the present invention provides a method for development of a correction factor for indirect method of life assessment of the transformer. The method comprises conducting accelerated ageing experiments on a model transformer. Specifically, stepped loading is applied on the model transformer to perform stress accelerated ageing experiment.

The method further comprises analyzing the deviations between the LoL (loss-of-life) curves obtained using the direct method and indirect method of life assessment of the transformer. The method furthermore comprises developing a correction factor based on accelerated ageing experiments conducted on the model transformer. The method also comprises modifying exponential coefficient of the said correction factor empirically to adapt for the equivalent ageing rate calculation of a transformer. The accuracy of the thermal model of life assessment of the transformer is attained using a correction factor based on an exponential factor of time, empirically formulated and introduced into the equivalent ageing rate equation of thermal model.

For better understanding of the present invention, the two different methods by which loss of life is calculated are described below.

Indirect method of life assessment of a transformer is done using loading and ambient temperature data of continuous nature which can be tracked on hourly basis from the SCADA systems or any other suitable means. The Hot Spot temperature calculations are related to ageing equations based on Arrhenius reaction rate equation. Transformer ageing rate factor, k, considering the effect of temperature, water and oxygen can be expressed as shown below.

$$k = A {e}^{\frac{{E}_{a}}{R ( T + 273 )}} \qquad ( 1 )$$

where T is the hot spot temperature in° C., Eₐ is the activation energy, A is the pre-exponential factor or contamination factor depending on the paper chemical environment including water, acidity and oxygen content and R is the molar gas constant.

A reference condition is considered of a dry thermally upgraded paper at a constant 110° C. with no oxygen access. The reference transformer ageing rate k₀ can be obtained as

$${k}_{0} = {A}_{0} {e}^{- \frac{{E}_{a 0}}{R ( {T}_{0} + 273 )}} \qquad ( 2 )$$

where, A₀ and E_{a 0} are the pre exponential factor and activation energy respectively under reference condition and T₀ is the reference temperature of 110° C.

Relative ageing rate, kᵣ, of thermal model is developed as the ratio of certain ageing rate, k, to reference ageing rate, k₀ , and given as

$${k}_{r} = \frac{k}{{k}_{0}} = \frac{A}{{A}_{0}} {e}^{[ \frac{{E}_{0}}{R ( {T}_{0} + 273 )} - \frac{E}{R ( T + 273 )} ]} \qquad ( 3 )$$

If the insulation paper chemical environment changes are neglected during the transformer operation, A and E are equivalent to the referenced A₀ and E₀ respectively. Hence kᵣ is simplified to

$${k}_{r} = {e}^{[ \frac{{E}_{0}}{R ( {T}_{0} + 273 )} - \frac{{E}_{0}}{R ( T + 273 )} ]} \qquad ( 4 )$$

Ageing acceleration factor, F_{AA}, as a function of only transformer hot spot temperature, T_{HS}, is same as Eq.4 of relative ageing rate and is given as

$${F}_{AA} = {e}^{( \frac{15000}{110 + 273} - \frac{15000}{{T}_{HS} + 273} )} \qquad ( 5 )$$

The value of F_{AA}is greater than 1 for hottest spot temperature T_{HS} greater than reference temperature 110° C., and lesser than 1 for temperatures below 110° C.

Equivalent ageing rate factor of the transformer at a reference temperature in a given time period T for a given temperature cycle is given by

$${F}_{eqa} = \frac{1}{T} {\int }_{0}^{F} {F}_{AA} dt \qquad ( 6 )$$

In discretized form, equivalent ageing rate factor

$${F}_{eqa} = \frac{{\sum }_{i = 1}^{N} {F}_{AAi} \times Δ ti}{{\sum }_{i = 1}^{N} Δ ti} \qquad ( 7 )$$

where, N is the number of discrete intervals in the time period T under consideration, which in turn depends on our choice of time interval Δt.

The actual loss of life is calculated by multiplying equivalent ageing rate factor, F_{eqa} by the time period T. The percent loss of life is given by

$$\% Loss of Life = \frac{{F}_{eqa} \times T}{Normal Insulation Life} \times 100 \qquad ( 8 )$$

Normal insulation life for power transformer is taken as 150000 hours or 17.12 years and distribution transformer's functional life as 180000 hours or 20.55 years.

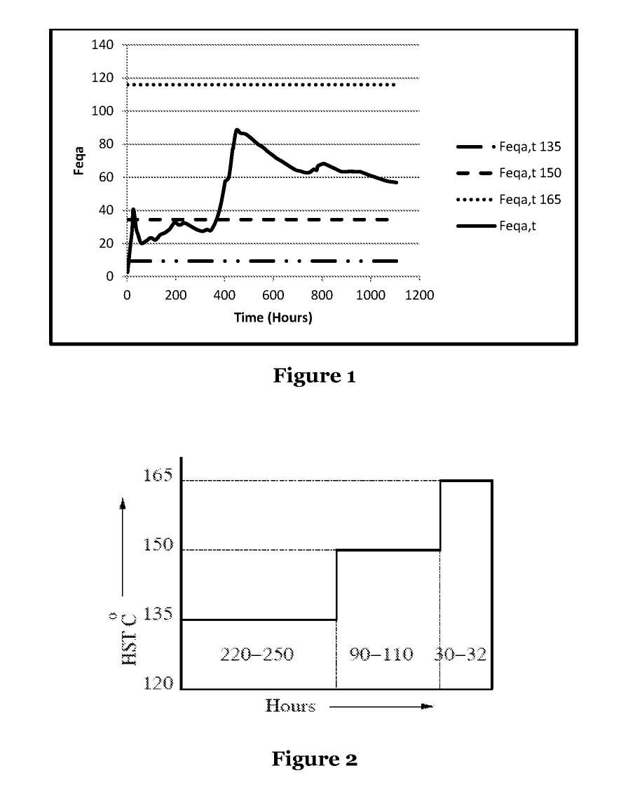

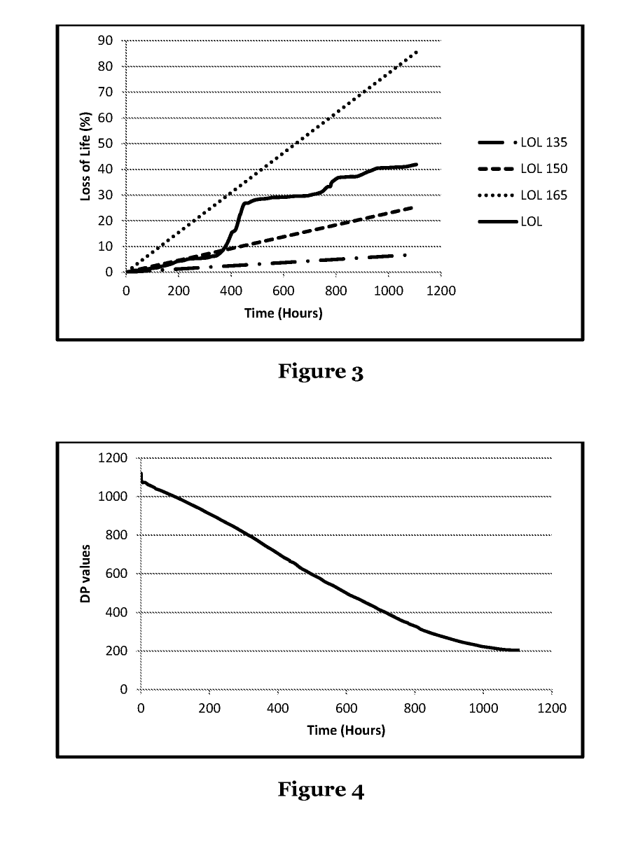

If hot spot temperature is maintained constant throughout the life of the transformer, equivalent ageing rate factor will be same as the ageing acceleration factor. In FIG. 1, equivalent ageing rate factor at constant hotspot temperatures of 135° C., 150° C., 165° C. throughout the operation of transformer are shown using different dashed lines. The solid line discusses another issue at a little later stage and may be neglected for now. Hence, it's clear from Eq.8 and FIG. 3 that the loss of life curves for a constant hot spot temperature is linear in nature.

The stepped loading applied on the model transformer to perform stress accelerated ageing experiment is shown in FIG. 2. Each loading cycle consists of three temperature levels and four such loading cycles are applied during the experimental time period.

Using thermal model which is the indirect method of calculation of LOL of the transformer, the loss of life is estimated from hot spot temperature profile of the transformer which in turn is obtained from loading and ambient temperature profiles of the transformer under operation. The equivalent ageing rate factor with time for the experimental temperature cycle is shown in solid line in FIG. 1 and the corresponding loss of life curve is plotted in FIG. 3. The variations in the Feqa and loss of life plots with time are due to the loading cycle applied.

The second method of loss of life calculation for the transformer or the direct method is discussed below. A chemical property of cellulose paper insulation which gives a fair idea about the condition of insulation is degree of polymerization (DP). The relationship between transformer ageing rate, k, with time, t, and DP is given by

$$\frac{1}{{DP}_{t}} - \frac{1}{{DP}_{0}} = kt \qquad ( 9 )$$

where, DP₀ is the initial DP value, DPₜ is the DP value at any time t and k is the transformer ageing rate which is assumed to be constant for this time duration.

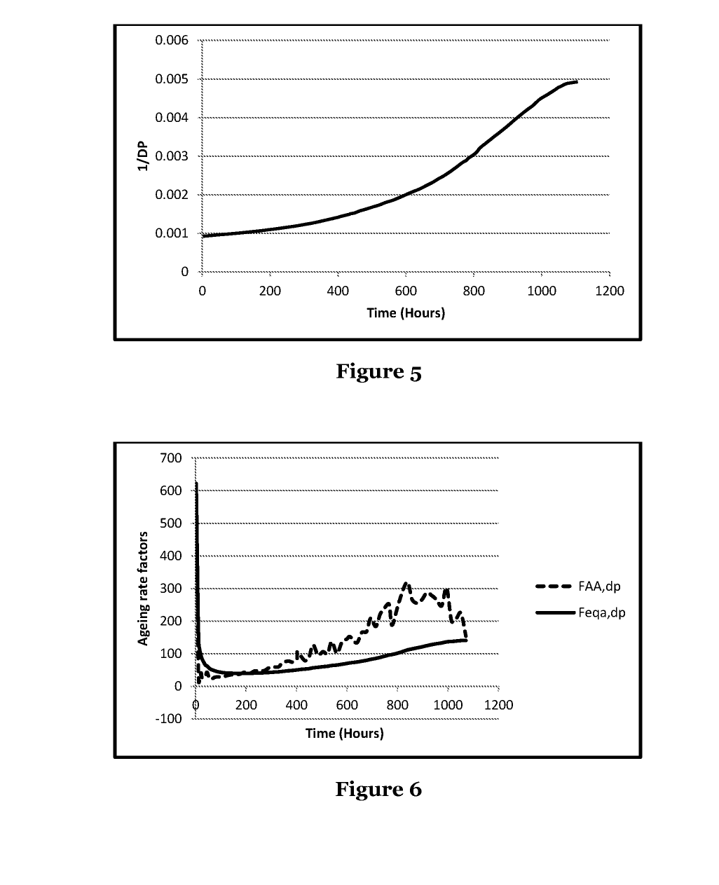

FIG. 4 shows the DP values with time measured during the experiment and DP shows a slight exponential decrease with time. DP value at the beginning of the experiment for the new insulation is 1126 which gradually decreases and reaches around 200 (one of the end of life criteria for the insulation) by the end of the experimental time. The variation of reciprocal of DP with time is given in FIG. 5 and is exponentially increasing in nature.

Eq. 9 is modified to obtain the absolute ageing rate, kᵢ, between two DP values for any time interval Δtᵢ

$${k}_{i} = \frac{\frac{1}{{DP}_{i}} - \frac{1}{{DP}_{i - 1}}}{Δ {t}_{i}} \qquad ( 10 )$$

Since the rupture of cellulose polymer chain occurs due to temperature, moisture and oxygen, change in DP value is as a result of the effects of all these factors. Hence the absolute ageing rate calculated using the Eq.10 is used to calculate the relative ageing rate factor, equivalent ageing rate factor and loss of life of the transformer.

In order to calculate the relative ageing rate factor, F_{AA,dp,i}, the reference ageing rate is calculated by Arrhenius equation (Eq.1) with reference temperature T of 110° C.

$${F}_{AA , dp , i} = \frac{absolute ageing rate , {k}_{i}}{reference ageing rate , {k}_{0}} = \frac{\frac{\frac{1}{{DP}_{i}} - \frac{1}{{DP}_{i - 1}}}{Δ {t}_{i}}}{A {e}^{- \frac{{E}_{a}}{R ( T + 273 )}}} \qquad ( 11 )$$

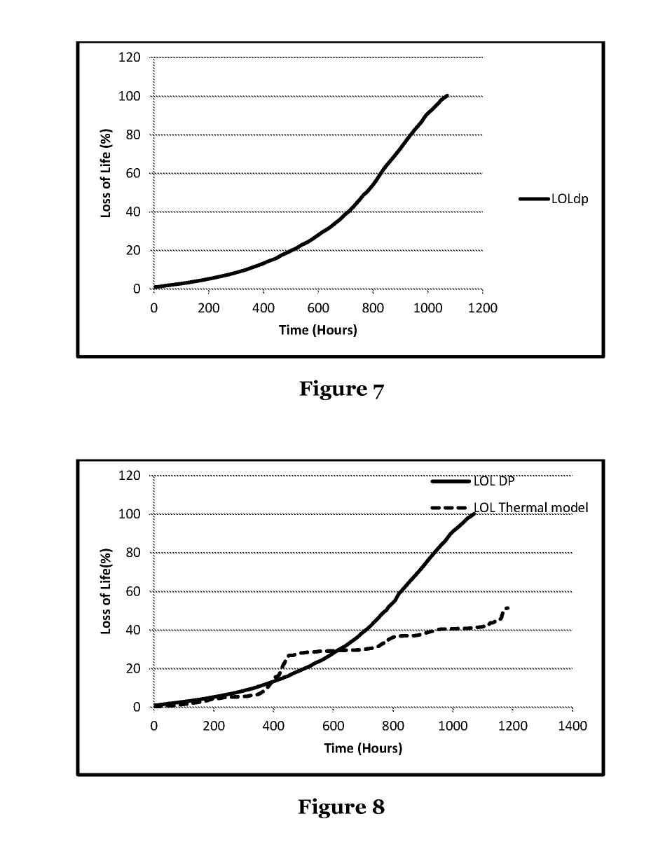

The equivalent ageing rate factor, F_{eqa}, and loss of life LOL_{dp} are calculated by the formulae in Eq.7 and Eq.8 using F_{AA,dp,i} (relative ageing rate factor, calculated using Eq.11) in place of F_{AAi} and F_{eqa,dp} in place of F_{eqa} respectively. FIG. 6 shows the relative ageing rate factor (F_{AA,dp,i}) and equivalent ageing rate factor (F_{eqa,dp}) with time. F_{AA,dp,i} is the value at each interval of time so an uneven graph of F_{AA,dp} with time is obtained which increases gradually and drops down towards the end of life. In contrast, F_{eqa,dp} is a weighted average with time so a slowly increasing function with time is obtained. The loss of life percentage accumulation against time by this method (applying eq. 8 with F_{eqa,dp}) is shown in FIG. 7.

FIG. 8 gives the loss of life curves from two methods, i.e. eq. (8) as original and eq. (8) with F_{eqa,dp} in place of F_{eqa}. The dissimilarity in the loss of life curve plotted by thermal model from the curve obtained by DP method is due to the assumption considered in the thermal model that only temperature is the factor that affects insulation deterioration. Thus, if the temperature is constant, loss of life increases linearly with time as shown in FIG. 3. Besides temperature, there are other agents responsible for degradation of insulation like water and oxygen. In direct method, which involves measurement of DP directly from the insulation, these causes get automatically incorporated. Hence, the loss of life curve from direct method or DP method is more accurate. In order to make the loss of life calculation by thermal model more precise and model the unaccounted factors, a correction factor is empirically formulated and introduced into the equivalent ageing rate factor equation Eq.6 of thermal model. The correction is done as an exponential factor of time. The modified equivalent ageing rate is given by the equation

$${F}_{eqa} = \frac{1}{T} {\int }_{0}^{T} {F}_{AA} \times {e}^{( 0.0006 \times t )} dt \qquad ( 12 )$$

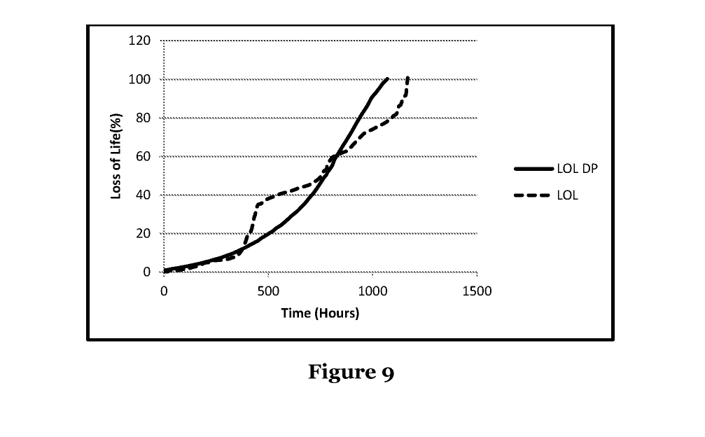

FIG. 9 shows that loss of life curve by thermal model with modified F_{eqa} (eq. 12) is similar to a significant extent to the LOL curve by DP method. The thermal model with modified F_{eqa} and loss of life calculation proposed above is applied to a transformer with power transformer specifications. The loading profile (in pu) is taken from that of a working transformer for one year using suitable means. It is assumed that the same yearly load pattern will continue in all the years that the transformer is working. This is a major assumption, but so far as an annual cycle is concerned, the net signed variations from the considered curve accumulated over the year can be considered near zero. The advantage acquired is that annual fluctuations are filtered out and it becomes feasible to compare losses across different periods of transformers life, as a function of age.

The ambient temperature for the corresponding one year is collected and the yearly ambient temperature pattern is considered to be the same in all the years of transformer operation.

The above mentioned load and ambient temperature pattern is used in the calculation of hot spot temperature. The modified formula of F_{eqa} needs the inclusion of a time scaling term and the resulting equation is given by

$${F}_{eqa} = \frac{1}{T} {\int }_{0}^{T} {F}_{AA} \times {e}^{( 0.0006 \times ( \frac{1070}{150000} ) \times t )} dt \qquad ( 13 )$$

where 1070/150000 is the term for time scaling. In the experiment, percent loss of life reaches 100 or life is completely consumed by 1070 hours when calculated by Direct Method (using DP values) which is equivalent to 150000 hours, the normal life expectancy of power transformers. This explains the logic behind this scaling factor.

For the validation of the above formula, different cases of load have been taken as shown in Table 1. The table shows that when 1 pu load on an average is applied to a transformer continuously throughout its life, the percent loss of life reaches 100% in 16.43 years which is near to the end of life criteria of 17.12 years of a power transformer. In particular it is observed that a heightened value of 10° C. of HST brings down the life span to a little less than half. Thus, substantiating the 10° Thumb Rule which states that the rate of deterioration of mechanical properties of insulation is doubled for each nearly 10 ° C. increase in temperature.

In accordance with the empirical formulation of F_{eqa} for power transformers, the formula of modified F_{eqa} for distribution transformer is developed and is given by

$${F}_{eqa} = \frac{1}{T} {\int }_{0}^{T} {F}_{AA} \times {e}^{( 0.0001 \times ( \frac{1070}{180000} ) \times t )} dt \qquad ( 14 )$$

where, 1070/180000 is the term for time scaling. In the experiment, percent loss of life reaches 100 or life is completely consumed by 1070 hours when calculated by Direct Method (using DP values) which is equivalent to 180000 hours which is the normal life expectancy of distribution transformers.

The distribution transformer characteristics and the loading pattern (in pu) and the ambient temperature pattern of a working transformer is considered as in the case of power transformer.

TABLE 1
Results of application of modifiedF_{eqa} for power transformers.

| | | Difference between |
|---|---|---|
| Average Load applied | | HST at 1 pu load from |
| (in pu) through | | HST obtained at |
| transformer life | Life (in years) | different load (° C.) |
| 1 | 16.43 | |
| 1.1 | 7.05 | 11.33 |
| 1.09 | 7.99 | 10.16 |

From the results in Table 2, it is evident that when a 1 pu average load is continuously applied throughout the life of the transformer, the transformer can work for 20.23 years which is close to the normal life expectancy of a distribution transformer of 20.55 years. For other two cases of accelerated loading, life has reduced to more than half which also serves to validate the approach on the basis of studies conducted on insulation materials previously. In particular, a heightened HST of 10° C. above values corresponding to design load levels reduces the life span to a little less than half.

TABLE 2
Results of application of modified F_{eqa} for distribution transformers.

| | | Difference between |
|---|---|---|
| Average Load applied | | HST at 1 pu load from |
| (in pu) through | | HST obtained at |
| transformer life | Life (in years) | different load (° C.) |
| 1 | 20.23 | |
| 1.1 | 7.046 | 11.04 |
| 1.09 | 8.04 | 9.9 |

### Technical Advancements

The technical advancements of the present INVENTION include the realization of:
A method that helps to provide an inexpensive, easy and less time consuming way of calculating the transformer ageing life;
A method that improves the existing thermal model using a correction factor to consider the effects of various ageing factors such as water, oxygen and temperature.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

The use of the expression “at least” or “at least one” suggests the use of one or more elements or ingredients or quantities, as the use may be in the embodiment of the INVENTION to achieve one or more of the desired objects or results.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

What is claimed:

1. A system for accurately monitoring and computing ageing life of a transformer in real-time, the system comprising:
a plurality of a power transformers distributed in at least one of power transmission network or power distribution network;
a computing platform connected to each transformer of the plurality of transformers, the computing platform having means to receive the data, a memory unit to store the data, a processor to execute instructions, and display device to display result; and
a module configured on the computing platform for computing and recording loads of transformer and ambient temperature at predefined interval,
wherein upon querying the computing platform, the module of the computing platform configured to introduce a correction factor, calculates and returns the value corresponding to the ageing life of a transformer.

2. A system for accurately monitoring and computing ageing life of a transformer as claimed in claim 1, wherein, the correction factor is developed by analyzing deviations between loss-of-life curves obtained using a direct method and an indirect method of life assessment of a transformer under same working conditions.

3. A system for accurately monitoring and computing ageing life of a transformer as claimed in claim 1, wherein the correction factor comprises a time scale factor as part of the exponential coefficient of the correction factor the value of which changes based on transformer type as a power transformer or a distribution transformer.

4. The system for accurately monitoring and computing ageing life of a transformer as claimed in claim 1, wherein the computing platform and a power transmission network are in real-time connection to capture the running hourly loss-of-life from the plurality of transformers.

5. The system for accurately monitoring and computing ageing life of a transformer as claimed in claim 1, wherein the ambient temperature of the transformer is measured using a weather thermometer.

6. The system for monitoring and computing an ageing life of the transformer as claimed in claim 1, wherein the ageing life of the transformer reduces to less than half due to deterioration of mechanical properties of insulation for each nearly 10° C. increase in temperature.

7. The method for development of a correction factor for an equivalent ageing rate calculation of a transformer by indirect method in a smart grid framework, the method comprising:
conducting accelerated ageing experiments on a model transformer, wherein stepped loading applied on the model transformer to perform stress accelerated ageing experiment;
analyzing the deviations between the Lot, (loss-of-life) curves obtained using the direct method and indirect method of life assessment of the transformer;
developing a correction factor based on analysis of the deviations between the LoL (loss-of-life) curves obtained using the direct method and indirect method;
including a time scale factor as an exponential coefficient of the correction factor and modifying the exponential coefficient of said correction factor empirically to adapt for the equivalent ageing rate calculation of the transformer, and
introducing said correction factor into an equivalent ageing rate equation of indirect method.

8. The method as claimed in claim 7, wherein the equivalent ageing rate of the transformer at a reference temperature in a given time period T for a given temperature cycle.

9. The method as claimed in claim 7, wherein the value of the exponential coefficient of the correction factor changes based on transformer type as a power transformer or a distribution transformer.
